(19) United States
(12) Patent Application Publication
(10) Pub. No.: US 2003/0006363 A1
(43) Pub. Date: Jan. 9, 2003

(54) Optimization of alignment between elements in an image sensor

(76) Inventors: Scott Patrick Campbell, Thousand Oaks, CA (US); Gennadiy Agranov, (US); Richard H. Tsai, Alhambra, CA (US); Eric R. Fossum, Wolfeboro, NH (US)

Correspondence Address: FISH & RICHARDSON, PC, 4350 LA JOLLA VILLAGE DRIVE, SUITE 500, SAN DIEGO, CA, 92122, US

(21) Appl. No.: 10/135,875

(22) Filed: Apr. 29, 2002

Related U.S. Application Data
(60) Provisional application No. 60/286,908, filed on Apr. 27, 2001.

(51) Int. Cl. H01L 27/00

(52) U.S. Cl. 250/208.1

(57) ABSTRACT

An image sensor formed with shifts between the optical parts of the sensor and the electrical parts of the sensor. The optical parts of the sensor may include a color filter array and/or microlenses. The photosensitive part may include any photoreceptors such as a CMOS image sensor. The shifts may be carried out to allow images to be received from a number of varying locations. The image shift may be, for example, at least half of the pixel pinch. The shift may be variable across the array or may be constant across the array and may be deterministically determined.

### CROSS-REFERENCE TO RELATED APPLICATIONS

The present application claims priority from provisional application No. 60/286,908, filed Apr. 27, 2001.

### BACKGROUND

Image sensors receive light into an array of photosensitive pixels. Each pixel may be formed of a number of cooperating elements including, for example, a lens, often called a “microlens”, a color filter which blocks all but one color from reaching the photosensitive portion, and the photosensitive portion itself. These elements are typically formed on different physical levels of a substrate.

It has typically been considered that the elements of the pixels should have their centers substantially exactly aligned. That is, the microlens, the color filter, and the photosensitive portion should each be substantially coaxial. The physical process used to create the semiconductor will have inherent errors, however, conventional wisdom attempts to minimize these errors.

### SUMMARY

The present application teaches a way to improve image acquisition through intentional shift between different optical parts of the optical elements in the array. This may be done to compensate for various characteristics related to acquisition of the image.

In an embodiment, the amount of shift may be variable throughout the array, to compensate for imaging lens angles. That is, the amount of shift at one location in the array may be different than the amount of shift at other locations in the array. Such a variable relative shift may also be used to obtain a three-dimensional view.

### BRIEF DESCRIPTION OF THE DRAWINGS

These and other aspects will now be described in detail with reference to the accompanying drawings, wherein:

FIG. 1 shows a layout of optical parts including microlens and color filter array which is aligned directly with its underlying photosensitive part;

FIG. 2 shows a layout of optical parts with a shift between the centers of the microlens/filter array and the photosensitive part;

FIG. 3 shows the effect of varying angles of incidence with shifts between microlens and image sensor;

FIG. 4 shows an improved technique where shifts between optical part and photosensitive part are configured to maintain the light incident to the proper photosensitive element;

FIG. 5 shows an exemplary light graph for a number of different angles of incidences;

FIGS. 6A and 6B show a graph of output vs. angle of incidence for a number of different angles of incidences.

### DETAILED DESCRIPTION

The present application teaches a photosensor with associated parts, including passive imaging parts, such as a lens and/or color filter, and photosensitive parts. An alignment between the imaging parts and the photosensitive parts is described.

The imaging parts may include at least one of a microlens and/or a filter from a color filter array. The photosensitive parts may include any photosensitive element, such as a photodiode, photogate, or other photosensitive part.

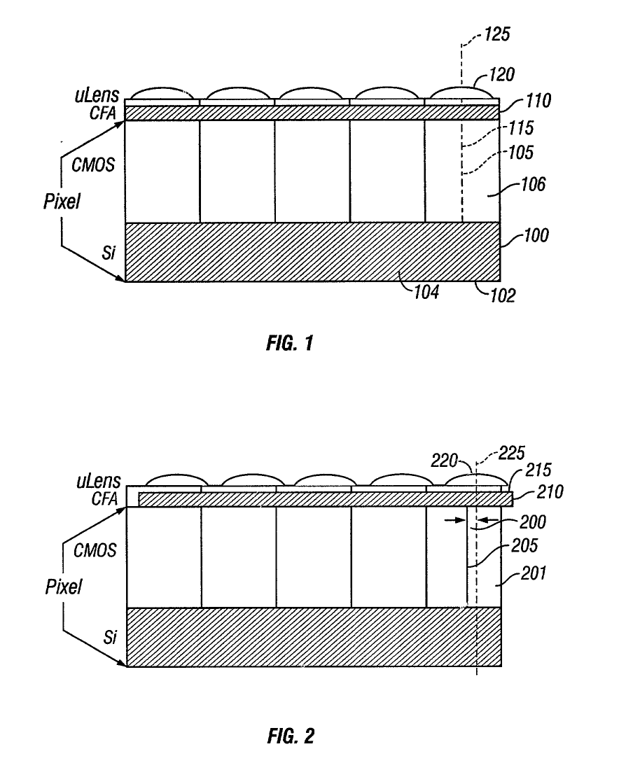

FIG. 1 shows a typical array used in an image sensor that is arranged into pixels, such as a CMOS image sensor array. The silicon substrate 100 is divided into a number of different pixel areas 102,104 . . . . Each different pixel area may include a photosensor 106 therein, for example a photodiode or the like. The photosensor is preferably a CMOS type photosensor such as the type described in U.S. Pat. No. 5,471,515. Each pixel such as 102 also includes a color filter 110 in a specified color. The color filters 110 collectively form a color filter array. Each pixel may also include an associated microlens 120. In FIG. 1, the center axis 125 of the microlens 120 substantially aligns with the center axis 115 of the color filter 110 which also substantially aligns with the center axis 105 of the CMOS photosensor 106.

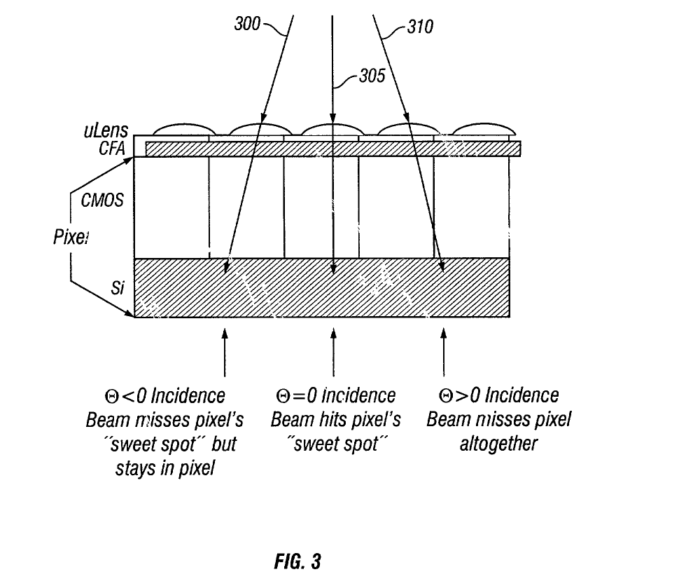

FIG. 2 shows an alternative embodiment in which the centers of the elements are shifted relative to one another. In the FIG. 2 embodiment, the center line 225 of the lens 220 may be substantially aligned with the center line 215 of the color filter 210. However, this center line 215/225 may be offset by an amount 200 from the line 205 of the photosensor 201 which represents the point of maximum photosensitivity of the photosensor 201. Line 205 may be the center of the photosensor. That is, the filters 210 and microlenses 220 have shifted centers relative to the line 205 of the photoreceptor 201. According to an embodiment, the amount of shift is controlled to effect the way the light is received into the photosensitive part of the pixels.

The shift between the pixels may be configured to minimize the crosstalk between neighboring pixels. This crosstalk may be spatial crosstalk between the neighboring pixels and spectral crosstalk within the pixel. In addition, the shift may be used to compensate for irregular beam angles during imaging, for example due to non telecentric imaging.

Relative shift between the microlenses and filter, and the photosensitive pixel centers, can vary across the detector array. According to an embodiment, the variable shift between the microlens/filter and pixel can be modeled according to the following equation:

$$S = D tan \{ {sin}^{- 1} [ \frac{sin ( θ )}{n} ] \} = D tan \{ {sin}^{- 1} [ \frac{sin ( \frac{Mr}{R} )}{n} ] \}$$

Where S is the variable shift between the center of the microlens and the center of peak photosensitivity or minimum crosstalk region of the pixel, shown as 200 in FIG. 2. This center line, shown as 205 in FIG. 2, may be variable as a function of beam entry angles. S represents the physical distance between the microlens center and pixel's peak photosensitive region. The variable θ represents the external beam entry angle, and n is the refractive index of the medium between the microlens and the photosensitive region of the pixel.

The beam entry angle θ can be replaced by the quotient Mr/R for general calculations, where M is the maximum beam angle of non-telecentricity, i.e. the maximum beam entry angle given at the maximum image point radius. The variable r is the image point radius under consideration for calculating S. R is the maximum image point radius.

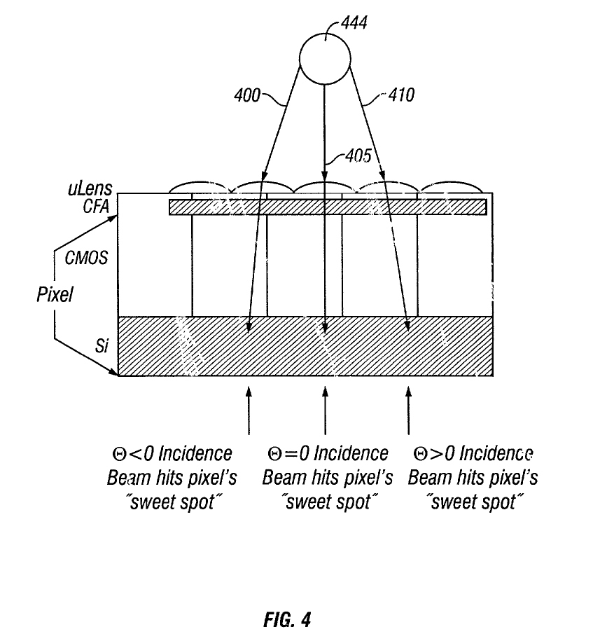

When the alignment between the optical elements are not nonzero (S≠0), the misalignment may cause crosstalk between neighboring pixels, and may cause beams to arrive from irregular angles in the image plane. This may be especially problematic when non telecentric lenses are used for imaging. FIG. 3 shows how light at different angles of incidences will strike the pixel bases at different locations. Beams which are incident at angles <0, such as beam 300, strike the base of the pixel near, but not at, the pixel's peak photosensitive region. That is, the beams remain in the pixel, but misses the specific “sweet spot” of maximum photosensitivity.

The beams which are incident at angles equal to zero, such as beam 305, hit exactly on the pixel's “sweet spot”, that is the area of maximum photosensitivity. Beams which are incident at other angles, such as beam 310, may, however, strike the base of the neighboring pixel. This forms spatial crosstalk.

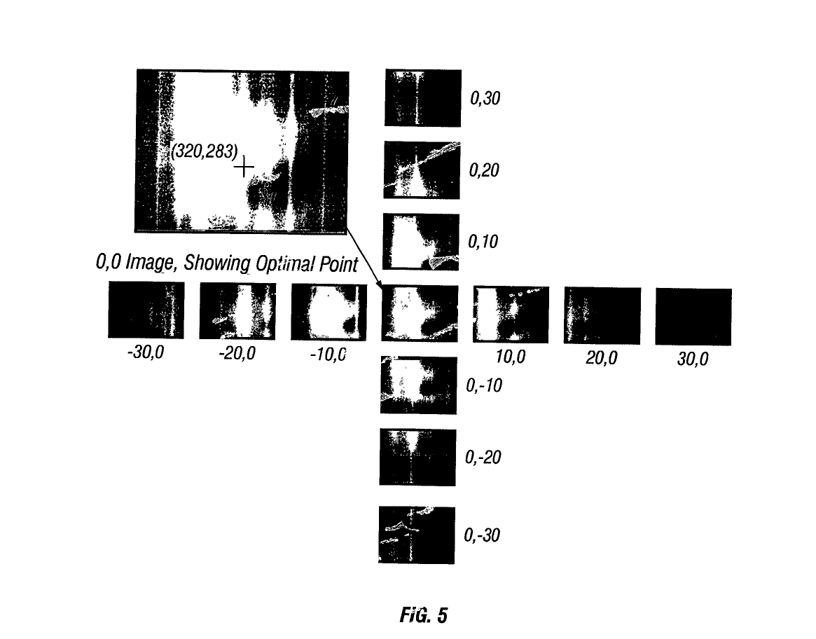

FIG. 4 shows the specific layout, with shifted pixel parts, which is used according to the present system. Each of the beams 400,405,410 are shifted by the lens and filter array such that each of the pixel photoreceptors hits a position of maximum photosensitivity of the CMOS image sensor.

To observe or test the performance of relative pixel shift as a function of beam incidence angle, numerous arrays can be fabricated with a single unique relative shift between the lens/filter and pixel center. A single array can also be used with deterministically varying relative shifts between the microlenses and pixels across the array. The array is illuminated at various angles of incidences and the response and crosstalk of the array is recorded. A single array may be fabricated with deterministically varying relative shift between the microlenses and pixel elements. The pixel may then be viewed three-dimensionally, at different angles of incidences. This may be used to test the performance of the trial and error determination.

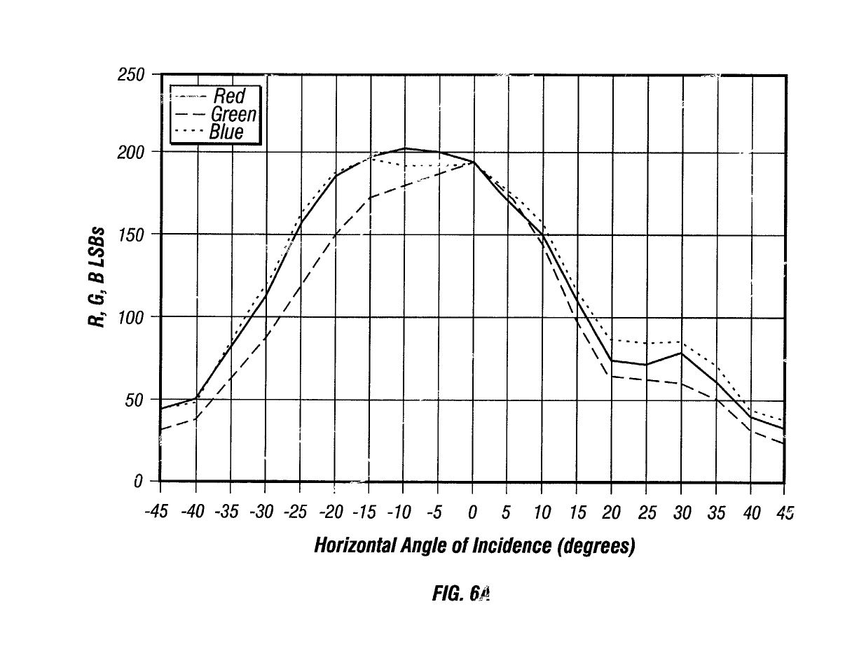

FIG. 5 shows a number of captured images. These images were captured using a CMOS image sensor whose micro lenses and filters were offset in the varying amount across the arrays similar to the technique shown in FIG. 4. Illumination in these images was quasi plane wave white light and incident at angles specified in each of the elements. The center of FIG. 5 shows the angle of incidence for the x=0, y=0 position. This output may be used to white balance the sensor output for optimal relative shift position. The other parts of the figure show the response of the sensor for different angles of incidence of the illuminating light.

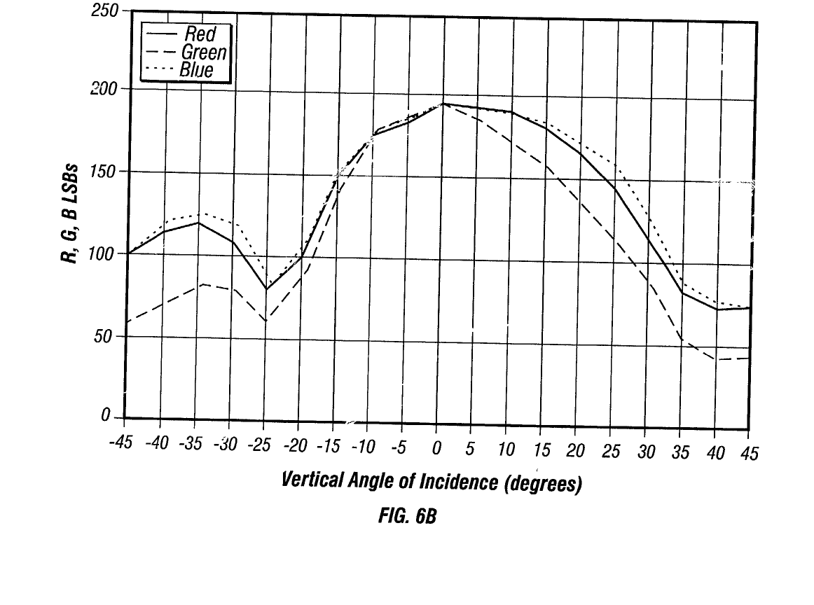

FIGS. 6A-6B show a graph which tracks the RGB values for the pixels under normal incidence with specially aligned microlenses as a function of incidence angles. FIG. 6A plots the RGB values for horizontal angles of incidence while FIG. 6B plots those RGB values for vertical angles of incidence. In both cases, the RGB values at 0, 0 are 196. This shows how the color and sensitivity varies according to the relative shift of the array for all of the varying angles of incidences.

The apparent motion of the pixel white balance under normal incident illumination may be tracked as the angle of incidence is varied. This may be compared to a variable shift between the microlenses and pixels. An optimum variable shift to compensate for given angles of incidence can be deterministically obtained.

For example, the sensor whose images are shown in FIG. 5 may benefit from a variable shift between the microlens, filters and pixels of 8 nm per pixel. This can be seen from the images in FIG. 5 which shows that the apparent motion is one pixel across −30 to +30 degrees. That represents 640 pixels horizontally for which there is a variable microlens shift of 8 nm per pixel. This enables calculating the total microlens shift of 5.12 microns. The corresponding variable shift microlens placement correction factor, for non telecentric imaging should therefore be 0.085 microns per degree.

Thus, for any image, there exists an additional one degree of non telecentricity. The relative shift between the microlens centers and pixel centers should hence be reduced towards the center of the array by 85 nm.

If the 85 nm per degree variable shift is substituted into equation 1, that is x=85 nm when θ equals one degree, and we assume a relative dielectric refractive index n=1.5, then the depth from the microlens to the specified feature comes out to 7.3 microns. This result is very close to the approximate value from the microlens lead the layer to the metal one (M1) layer in the array under examination.

The microlenses according to this system may be spherical, cylindrical, or reflowed square footprint lenses. Non telecentric optics may be used.

An aspect of this system includes minimizing the crosstalk from the resulting received information. Crosstalk in the image sensor may degrade the spatial resolution, reduce overall sensitivity, reduce color separation, and lead to additional noise in the image after color correction. Crosstalk in CMOS image sensors may generally be grouped as spectral crosstalk, spatial optical crosstalk, and electrical crosstalk.

Spectral crosstalk occurs when the color filters are imperfect. This may pass some amount of unwanted light of other colors through the specific filter.

Spatial optical crosstalk occurs because the color filters are located a finite distance from the pixel surface. Light which impinges at angles other than orthogonal may pass through the filter. This light may be partially absorbed by the adjacent pixel rather than the pixel directly below the filter. The lens optical characteristics, e.g. its F number, may cause the portion of the light absorbed by the neighboring pixel to vary significantly. Microlenses located atop the color filters may reduce this complement of crosstalk.

Electrical crosstalk results from the photocarriers which are generated from the image sensor moving to neighboring charge accumulation sites. Electrical crosstalk occurs in all image sensors including monochrome image sensor. The quantity of crosstalk in carriers depends on the pixel structure, collection areas size and intensity distribution.

Each of these kinds of crosstalk can be graphed, and the optimum shift for the crosstalk reduction can be selected. For example, each of the spectral crosstalk, optical crosstalk and electrical crosstalk can be separately viewed. The different types of crosstalk can then be separately optimized.

Other embodiments are within the disclosed invention.

What is claimed is:

1. An image sensor, comprising:
an array of optical parts at specified pixel locations; and
an array of photosensitive parts, also arranged in an array with different photosensitive parts at said specified pixel locations;
said optical parts and photosensitive parts arranged such that there is a relative nonzero shift between a line of maximum photosensitivity region of the photosensitive part, and an optical center line of the optical part, for at least a plurality of said pixel locations.

2. An image sensor as in claim 1, wherein said relative shift is the same for all pixel locations of the array.

3. An image sensor as in claim 1, wherein said shift is variable among different pixel locations in the array.

4. An image sensor as in claim 1, wherein said optical parts include at least one microlens.

5. An image sensor as in claim 4, wherein said optical parts also include a color filter array, having a plurality of different colored filters.

6. An image sensor as in claim 1, wherein said optical parts include a color filter array.

7. An image sensor as in claim 1 wherein said photosensitive parts include a CMOS image sensor.

8. As image sensor as in claim 1, wherein said shift is at least half a pixel pitch.

9. An image sensor, comprising:
an array of pixels, each pixel comprising:
a photosensitive part, having a first area of peak photosensitivity;
a color filter, having a property to allow transmission of a specified color of light, located optically coupled to said photosensitive part; and
a microlens, optically coupled to said photosensitive part;
both said color filter and said microlens having a central axis, and wherein said central axis is intentionally offset from said first area of peak photosensitivity of said photosensitive part.

10. An image sensor as in claim 9, wherein an amount of said offset is the same for each of said pixels of said array of pixels.

11. An image sensor as in claim 9, wherein an amount of said offset is different for pixels in certain locations in the array then it is for pixels in other locations in the array.

12. An image sensor as in claim 9, wherein said photosensitive part is a CMOS image sensor part.

13. An image sensor as in claim 9, wherein said photosensitive part includes a photodiode.

14. An image sensor as in claim 9, wherein said offset is by an amount S, according to
$$S = D tan \{ {sin}^{- 1} [ \frac{sin ( θ )}{n} ] \} = D tan \{ {sin}^{- 1} [ \frac{sin ( \frac{Mr}{R} )}{n} ] \}$$
Where θ represents the external beam entry angle, and n is the refractive index of the medium between the microlens and the photosensitive region of the pixel, M is the maximum beam angle of non-telecentricity, and r is the image point radius under consideration for calculating S.

15. An image sensor as in claim 9, wherein said offset is by an amount that causes all beams from all incidence angles of interest to remain within the same pixel.

16. An image sensor as in claim 9, wherein said shift is 5.12 microns.

17. A method, comprising:
using a model to calculate an amount of shift between a passive imaging part of a photodetector array and a photosensitive part of the photodetector array, and intentionally offsetting a center point of said passive part from the specified point of said photosensitive part.

18. A method as in claim 17, wherein said model is according to
$$S = D tan \{ {sin}^{- 1} [ \frac{sin ( θ )}{n} ] \} = D tan \{ {sin}^{- 1} [ \frac{sin ( \frac{Mr}{R} )}{n} ] \}$$
Where θ represents the external beam entry angle, and n is the refractive index of the medium between the microlens and the photosensitive region of the pixel, M is the maximum beam angle of non-telecentricity, and r is the image point radius under consideration for calculating S.

19. A method as in claim 17, wherein said specified point of said photosensitive part is a position of maximum photosensitivity.

20. A method as in claim 17, wherein said passive imaging part includes at least a microlens.

21. A method as in claim 17, wherein said passive imaging part includes at least a color filter.

22. A method as in claim 21, wherein said passive imaging part includes at least a microlens.

23. A method as in claim 22, wherein said offsetting comprises offsetting certain elements of said photodetector array more than other elements of said photodetector array.

24. A method, comprising:
forming a photoreceptor array which has an intentional shift between passive elements of the array, and positions of maximum sensitivity of the photoreceptor.

25. A method as in claim 24, further comprising determining an amount of said intentional shift by trial and error.

26. A method as in claim 24, further comprising determining an amount of said intentional shift by using a model.

27. A method as in claim 26, wherein said model includes:
$$S = D tan \{ {sin}^{- 1} [ \frac{sin ( θ )}{n} ] \} = D tan \{ {sin}^{- 1} [ \frac{sin ( \frac{Mr}{R} )}{n} ] \}$$
Where θ represents the external beam entry angle, and n is the refractive index of the medium between the microlens and the photosensitive region of the pixel, M is the maximum beam angle of non-telecentricity, and r is the image point radius under consideration for calculating S.

28. A method as in claim 25, wherein said trial and error comprises forming a plurality of different arrays having different shifts, illuminating said the arrays at various angles of incidence, and analyzing both response and crosstalk of the array.

29. A method as in claim 27, wherein said analyzing crosstalk comprises separately analyzing spectral crosstalk, optical crosstalk, and electrical crosstalk.

30. A method as in claim 29, wherein said separately analyzing comprises graphing the different types of crosstalk.

31. The method as in claim 24, further comprising looking at different images obtained from analysis at different illumination levels, determining an apparent motion of the image across the pixels, and determining and desired microlens shift from the apparent motion.

32. A method, comprising:
analyzing crosstalk in a photoreceptor array; and
using said analyzing to determine an amount of shift between passive elements of the photodetector array and photoreceptive elements of the photodetector array.

33. A method as in claim 32, wherein said analyzing crosstalk comprises analyzing separately spectral crosstalk, optical crosstalk, and electrical crosstalk.

34. A method as in claim 33, wherein said analyzing crosstalk comprises graphing said crosstalk.

35. And image sensor, comprising:
a passive optical portion including at least one of a microlens or a color filter, having a central axis portion; and
a photosensor, having a position of peak photosensitivity which is intentionally offset from said central axis portion by a nonzero amount, said nonzero amount being related to a position of desired imaging.

36. An image sensor as in claim 35, wherein said image sensor includes an array of pixels, each pixel formed from a passive optical portion and a photosensor.

37. An image sensor as in claim 36, wherein each of said pixels has the same amount of said intentional offset.

38. An image sensor as in claim 36, wherein some of said pixels have a different offset than others of said pixels.
